(19) United States
(12) Patent Application Publication
(10) Pub. No.: US 2021/0372944 A1
(43) Pub. Date: Dec. 2, 2021

(54) ANALYSIS APPARATUS AND IMAGE CREATION METHOD

(71) Applicant: Tokyo Electron Limited, Tokyo (JP)

(72) Inventor: Shin UCHIDA, Nirasaki City, Yamanashi (JP)

(21) Appl. No.: 17/299,989

(22) PCT Filed: Nov. 28, 2019
(86) PCT No.: PCT/JP2019/046568

§ 371 Date: Jun. 4, 2021

(30) Foreign Application Priority Data
Dec. 11, 2018 (JP) 2018-231670

(51) Int. Cl. G01N 21/95; G01R 1/073; G01R 31/28; G01R 1/02

(52) U.S. Cl. CPC G01N 21/9501; G01R 1/07342; G06T 7/0004; G01R 1/025; G01R 31/2886

(57) ABSTRACT

An analysis apparatus, which is for analyzing a state of inspection of an object to be inspected having inspection target devices formed on the object to be inspected by using a probe card having probes formed on the probe card and configured to be brought into contact with the inspection target devices, includes a display part configured to display an image and an image creator configured to create the image to be displayed on the display part, wherein the image creator creates, based on a result of detecting at least one of heights of the probes in portions of the probe card and heights of the inspection target devices in portions of the inspection object, a height map image showing a distribution of the heights of at least one of the probes and the inspection target devices.

This is a National Phase Application filed under 35 U.S.C. 371 as a national stage of PCT/JP2019/046568, filed Nov. 28, 2019, an application claiming the benefit of Japanese Application No. 2018-231670, filed Dec. 11, 2018, the content of each of which is hereby incorporated by reference in its entirety.

### TECHNICAL FIELD

The present disclosure relates to an analysis apparatus and an image creation method.

### BACKGROUND

Patent Document 1 discloses a method of adjusting inclination of a probe card attached to an inspection apparatus when performing an electrical characteristic inspection of an object to be inspected by collectively bringing a plurality of probes of the probe card into electrical contact with the object to be inspected. In such a method, average heights of needle tips of the plurality of probes can be detected at a plurality of locations on the probe card by using a needle tip position detection device, thereby calculating the inclination of the probe card based on the average heights of the needle tips of the plurality of probes at the respective locations. Then, based on the calculation result, the inclination of the probe card is adjusted.

### PRIOR ART DOCUMENT

### Patent Document

Patent Document 1: Japanese Laid-Open Patent Publication No. 2009-204492

### SUMMARY

A technique according to the present disclosure makes it easy to visually recognize at least one of a distribution of heights of probes provided on a probe card and a distribution of heights of inspection target devices formed on an object to be inspected.

An aspect of the present disclosure is an analysis apparatus for analyzing a state of inspection of an object to be inspected. The object to be inspected has inspection target devices formed on the object to be inspected, and the inspection is performed by using a probe card having probes, which is formed on the probe card and configured to be brought into contact with the inspection target devices. The analysis apparatus includes a display part configured to display an image and an image creator configured to create the image to be displayed on the display part. The image creator creates as the image, based on a result of detecting at least one of heights of the probes in portions of the probe card and heights of the inspection target devices in portions of the object to be inspected, a height map image showing a distribution of the heights of at least one of the probes and the inspection target devices.

According to the present disclosure, at least one of a distribution of heights of probes provided on a probe card and a distribution of heights of inspection target devices formed on an object to be inspected can be easily visually recognized.

### BRIEF DESCRIPTION OF DRAWINGS

FIG. 1 is a view illustrating a schematic configuration of a monitoring system including an analysis apparatus according to an embodiment.

FIG. 2 is a top horizontal cross-sectional view illustrating a schematic configuration of an inspection apparatus.

FIG. 3 is a front vertical cross-sectional view illustrating the schematic configuration of the inspection apparatus.

FIG. 4 is a front vertical cross-sectional view illustrating a configuration in a division region of the inspection apparatus.

FIG. 5 is a partially enlarged view of FIG. 4.

FIG. 6 is a view illustrating a schematic configuration of an analysis apparatus.

FIG. 7 is a view illustrating an exemplary probe height map image.

FIG. 8 is a view illustrating another exemplary probe height map image.

FIG. 9 is a view illustrating an exemplary user interface image including a height map image.

FIG. 10 is a flowchart illustrating an exemplary image creation process executed by an image creator.

FIG. 11 is a view illustrating an exemplary user interface image including an image representing a temporal change of probe heights in a specific portion in a horizontal plane.

FIG. 12 is a view illustrating an exemplary user interface image for displaying the user interface image of FIG. 11.

### DETAILED DESCRIPTION

In a semiconductor manufacturing process, a number of electronic devices each having a circuit pattern are formed on a semiconductor wafer (hereinafter, referred to as a “wafer”). The formed electronic devices are subjected to an inspection such as an electrical characteristic inspection, and are sorted into non-defective products and defective products. The inspection of electronic devices is performed by using an inspection apparatus, for example, in a state of a wafer before being divided into individual electronic devices.

An electronic device inspection apparatus called a prober or the like is provided with a probe card having probes, which come into contact with electronic devices. In the inspection apparatus, whether or not the electronic devices are defective is determined based on electric signals from the electronic devices detected by the probes.

In recent years, in order to collectively inspect a large number of electronic devices formed on a wafer, a large number of probes are also provided on a probe card, and the probes are collectively brought into contact with the electronic devices during the inspection.

Heights of the probes in respective portions of the probe card or heights of the electronic devices in respective portions of the wafer affect the above-mentioned collective contact. Therefore, the heights of the probes are detected at a plurality of locations on the probe card, and the heights of the electronic devices are detected at a plurality of locations on the wafer. When a user (e.g., an administrator of the inspection apparatus) can recognize in-plane tendency of the heights of the probes or the electronic devices from the detection results described above, it is possible to use the in-plane tendency for analyzing inspection results of the electronic devices or the like.

However, when the detection results of the heights of the probes at a plurality of locations on the probe card are simply displayed, it is not easy to recognize the in-plane tendency of the heights of the probes, that is, in-plane distribution of the heights of the probes, from the displayed content. The same applies to the in-plane tendency of the heights of electronic devices.

Therefore, a technique according to the present disclosure makes it easy to visually recognize a distribution of at least one of heights of probes provided on a probe card and a distribution of heights of inspection target devices formed on an object to be inspected.

Hereinafter, an analysis apparatus and an image creation method according to the present embodiment will be described with reference to the drawings. In the specification and drawings, elements having substantially the same functional configuration will be denoted by the same reference numerals, and redundant explanations will be omitted.

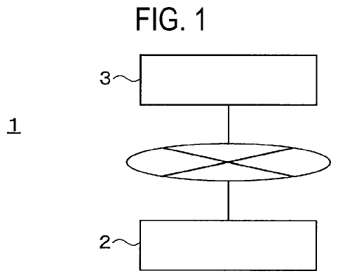

FIG. 1 is a view illustrating a schematic configuration of a monitoring system 1 including an analysis apparatus according to the present embodiment.

A monitoring system 1 of FIG. 1 monitors an inspection apparatus 2, and includes the inspection apparatus 2 and an analysis apparatus 3. In the monitoring system 1, the inspection apparatus 2 and the analysis apparatus 3 are connected to each other via a network such as a local area network (LAN) or the Internet. In addition, for the sake of simplification of the description, one inspection apparatus 2 is connected to one analysis apparatus 3 in the example of FIG. 1, but a plurality of inspection apparatuses 2 may be connected.

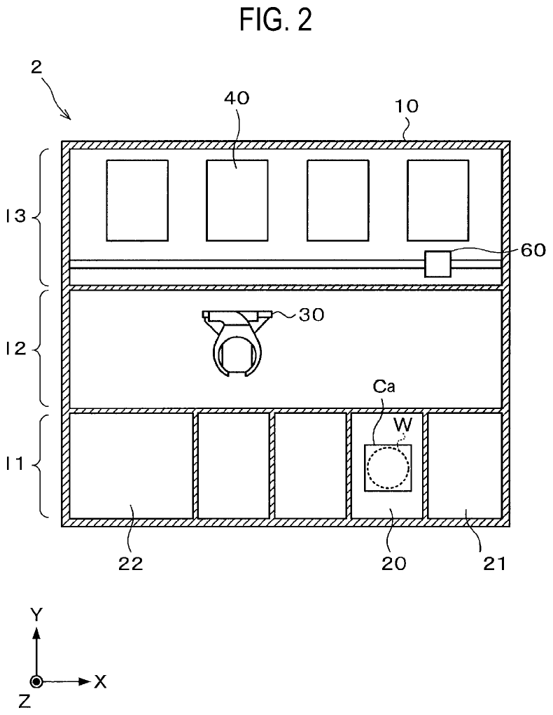

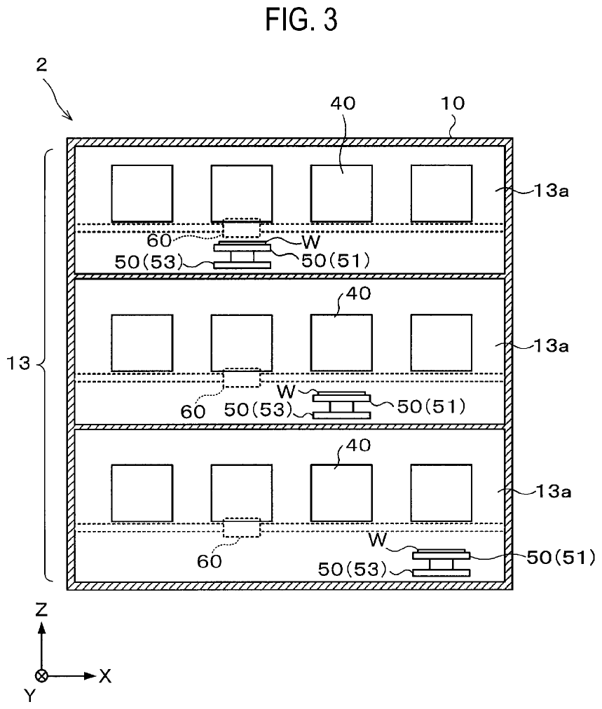

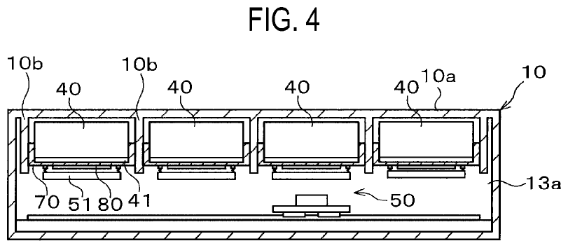

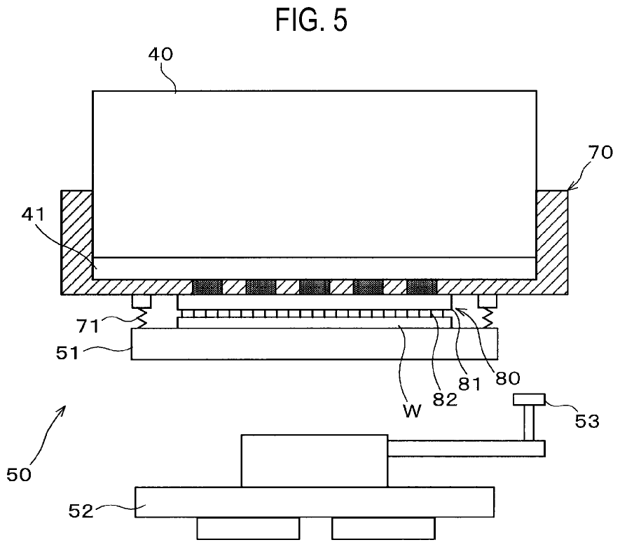

FIGS. 2 and 3 are a top horizontal cross-sectional view and a front vertical cross-sectional view, respectively, each of which illustrates a schematic configuration of the inspection apparatus 2. FIG. 4 is a front vertical cross-sectional view illustrating a configuration in a division region 13a of the inspection apparatus of FIGS. 2 and 3. FIG. 5 is a partially enlarged view of FIG. 4. In addition, a lower camera, which will be described later, is illustrated only in FIG. 5.

As illustrated in FIGS. 2 and 3, the inspection apparatus 2 includes a housing 10, and a loading and unloading region 11, a transfer region 12, and an inspection region 13 are provided in the housing 10. The loading and unloading region 11 is a region for loading and unloading a wafer W as an object to be inspected with respect to the inspection apparatus 2. The transfer region 12 is a region that connects the loading and unloading region 11 and the inspection region 13. The inspection region 13 is a region in which electrical characteristics of electronic devices formed on the wafer W are inspected.

The loading and unloading region 11 is provided with a port 20 configured to accommodate a cassette Ca accommodating a plurality of wafers W, a loader 21 configured to accommodate a probe card, and a controller 22 configured to control respective components of the inspection apparatus 2. The controller 22 is configured by a computer having, for example, a CPU and a memory.

In the transfer region 12, a transfer device 30 configured to be freely movable in a state of holding, for example, the wafer W, is disposed. The transfer device 30 transfers the wafer W between the cassette Ca in the port 20 of the loading and unloading region 11 and the inspection region 13. In addition, the transfer device 30 transfers a probe card, which is one among probe cards fixed to a pogo frame to be described later in the inspection region 13 and requires maintenance, to the loader 21 in the loading and unloading region 11. In addition, the transfer device 30 transfers a new probe card or a probe card having been subjected to the maintenance from the loader 21 to the pogo frame in the inspection region 13.

A plurality of testers 40 is provided in the inspection region 13. Specifically, as illustrated in FIG. 3, the inspection region 13 is divided in a vertical direction into three regions, and each division region 13a is provided with a tester row including four testers 40 arranged in a horizontal direction (an X direction in the drawings). Hereinbelow, a space in which each tester 40 is provided may be referred to as a stage. In addition, each division region 13a is provided with one position alignment part 50 and one upper camera 60. The numbers and arrangements of the testers 40, position alignment parts 50, and upper camera 60 may be arbitrarily selected.

Each tester 40 transmits and receives an electric signal for electrical characteristic inspection to and from the wafer W.

The position alignment part 50 is configured to place a wafer W thereon and to perform position alignment between the wafer W placed thereon and probe cards disposed below the testers 40. The position alignment part 50 is provided so as to be movable in a region below the testers 40.

The upper camera 60 images an upper surface of a wafer W located below the upper camera 60. Specifically, the upper camera 60 images a predetermined portion of an electronic device (e.g., a pad formed in the electronic device) as an inspection target device formed on a top surface of the wafer W. An imaging result by the upper camera 60 is used in the inspection apparatus 2 for a position alignment between the probe cards arranged below the testers 40 and the wafer W placed on the position alignment part 50, for example, as will be described later. In addition, the upper camera 60 is configured to be movable horizontally. Therefore, for example, during the position alignment, the upper camera 60 may be positioned in front of each tester 40 in the division region 13a provided with the upper camera 60.

In the inspection apparatus 2 configured as described above, while the transfer device 30 transfers one wafer W toward one tester 40, another tester 40 may perform electric characteristics inspection of electronic devices formed on another wafer W.

Next, a configuration related to the testers 40 and the position alignment part 50 will be described.

As illustrated in FIGS. 4 and 5, each tester 40 has a tester motherboard 41 provided horizontally on a bottom portion thereof. A plurality of test circuit boards (not illustrated) is mounted on the tester motherboard 41 in an upright state. In addition, a plurality of electrodes is provided on a bottom surface of the tester motherboard 41.

In addition, below each tester 40, a pogo frame 70 and a probe card 80 are provided in this order from above.

The pogo frame 70 is configured to support the probe card 80 and electrically connect the probe card 80 and the tester 40 (specifically, the electrodes on the bottom surface of the tester motherboard 41) with each other. The pogo frame 70 is arranged to be located between the tester 40 and the probe card 80.

The probe card 80 is held on a bottom surface of the pogo frame 70 by vacuum-suction in a state of being positioned at a predetermined position.

In addition, a bellows 71 extending vertically downward is attached to the bottom surface of the pogo frame 70 so as to surround the installation position of the probe card 80. The bellows 71 is to form, in a state in which a wafer W on a chuck top (described later) is in contact with the probes (described later) of the probe card 80, a sealed space including the probe card 80 and the wafer W.

The probe card 80 has a disk-shaped card main body 81, and further includes a plurality of probes 82, which are needle-shaped terminals extending downward from a bottom surface of the card main body 81. At the time of inspecting electrical characteristics of a plurality of electronic devices formed on a wafer W, the plurality of probes 82 is collectively brought into contact with the plurality of electronic devices, and electric signals related to the inspection are transmitted and received between the tester motherboard 41 and each electronic device on the wafer W via each probe 82.

The position alignment part 50 is configured to place a chuck top 51, which is configured to place a wafer W thereon and to hold the wafer W placed thereon by suction or the like, thereon.

In addition, the position alignment part 50 includes an aligner 52. The aligner 52 is a position adjusting mechanism configured to hold the chuck top 51, on which the wafer W is placed, by vacuum suction or the like, and to perform a position alignment between the wafer W placed on the chuck top 51 and the probe 82 during an electrical characteristic inspection. The aligner 52 is configured to be movable in the vertical direction (a Z direction in the drawings), a front-rear direction (a Y direction in the drawings), and the left-right direction (the X direction in the drawings) in a state of holding the chuck top 51.

By moving the aligner 52, positions of the wafer W on the chuck top 51 and the probe 82 of the probe card 80 are aligned so that the sealed space including the probe card 80 and the wafer W can be formed by the bellows 71 or the like. When the sealed space is vacuum-evacuated by a vacuum mechanism (not illustrated) to release the holding of the chuck top 51 by the aligner 52 and the aligner 52 is moved downward, the chuck top 51 is separated from the aligner 52 and suctioned to a side of the pogo frame 70. In this state, the electrical characteristic inspection is performed.

In addition, the position alignment part 50 is provided with a lower camera 53. The lower camera 53 images the probes 82 located above the lower camera 53 before the chuck top 51 is suctioned to the side of the pogo frame 70, that is, before the probes 82 of the probe card 80 and the wafer W are brought into contact with each other. This imaging result is used in the inspection apparatus 2 for performing a position alignment between the imaged probe 82 and the wafer W placed on the position alignment part 50, for example, as will be described later.

In the inspection apparatus 2 having the above-described testers 40 and position alignment part 50, a position alignment (hereinafter referred to as “alignment”) between the electronic devices formed on the wafer W and the probes 82 is performed prior to the electrical characteristic inspection. In such an alignment, positions of the electronic devices in a plurality of portions on the wafer W are detected based on the imaging result by the upper camera 60, and positions of the probes 82 in a plurality of portions on the probe card 80 are detected based on the imaging result by the lower camera 53. The detection result of the positions of the electronic devices and the detection result of the positions of the probes 82 are acquired by the controller 22 of the inspection apparatus 2 as alignment information (hereinafter, also referred to as “alignment log”).

The alignment log also includes information on positions in a height direction (i.e., heights) of the electronic devices and the probes 82. A unit for acquiring the alignment log is not particularly limited, but in the following example, it is assumed that the alignment log is acquired on an aligner unit basis and a daily basis.

The inspection apparatus 2 outputs a part or all of the alignment log to the analysis apparatus 3 via the network.

A height of an electronic device included in the alignment log output to the analysis apparatus 3 is, for example, a height of a specific portion (e.g., an electrode pad) of the electronic device with respect to a reference position, in other words, a deviation from the reference position. A height of a probe 82 is, for example, a height of a tip end of the probe 82 with respect to the reference position. The reference position of the electronic devices is set for, for example, each wafer W and the reference position of the probes 82 is set for, for example, each probe card 80.

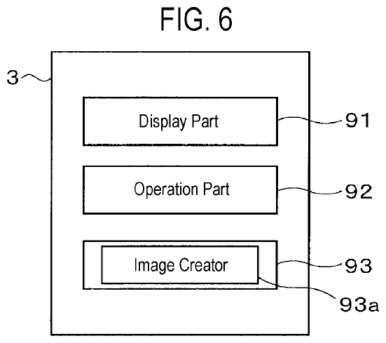

FIG. 6 is a view illustrating a schematic configuration of the analysis apparatus 3.

The analysis apparatus 3 includes a display part 91, an operation part 92, and a controller 93.

The display part 91 displays various images, and is configured by, for example, a liquid crystal display or an organic EL display.

The operation part 92 is a part for receiving an operation input from the user, and is configured by, for example, a keyboard or a mouse.

The controller 93 is a computer including, for example, a CPU and memory, and includes a program storage (not illustrated). A program for controlling a process in the analysis apparatus 3 is stored in the program storage. In addition, a program for implementing an image creation process to be described later is also stored in the program storage. The programs may be recorded in a computer-readable storage medium, and may be installed on the controller 93 from the storage medium.

The controller 93 includes an image creator 93a configured to create an image to be displayed on the display part 91. The image creator 93a is implemented in the controller 93 by a processing of the CPU according to instructions of a program written in, for example, an object-oriented programming language.

The image creator 93a creates an image for analyzing a state of the inspection by the inspection apparatus 2 (hereinafter, an “image for analysis”) based on the alignment log output from the inspection apparatus 2. The analysis of the inspection state includes not only analyzing the inspection result, but also confirming states of the probes 82 or the electronic devices at a time point before the inspection.

Specifically, the image creator 93a creates, as an image for analysis, a probe height map image representing an in-plane distribution of the heights of the probes 82 in the probe card 80 based on the detection result of the heights of the probes 82 in the plurality of portions on the probe card 80, which is included in the alignment log. In addition, the image creator 93a creates, as an image for analysis, a device height map image representing an in-plane distribution of the heights of the electronic devices in the wafer W based on the detection result of the heights of the electronic devices in the plurality of portions on the wafer W, which is included in the alignment log.

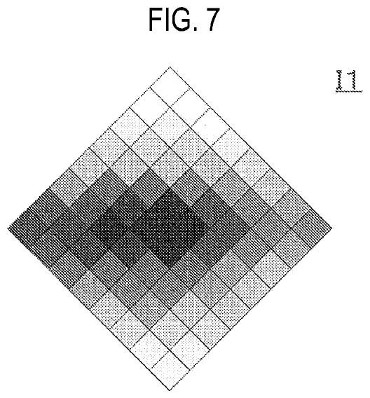

FIG. 7 is a view illustrating an exemplary probe height map image created by the image creator 93a.

A probe height map image It of FIG. 7 displays the in-plane distribution of the heights of the probes 82 (hereinafter, referred to as a “probe height distribution”) as a plane image, and represents height information of the probes 82 in color.

In the example of FIG. 7, the heights of the probes 82 are indicated by a change in brightness. Specifically, portions having small heights are indicated by a low brightness whereas portions having large heights are indicated by a high brightness. The present disclosure is not limited to this example. As long as the probe height distribution can be easily recognized, the heights of the probes 82 may be indicated by a change in saturation or a change in hue, or may be indicated by a combination of two or more of brightness, saturation, and hue.

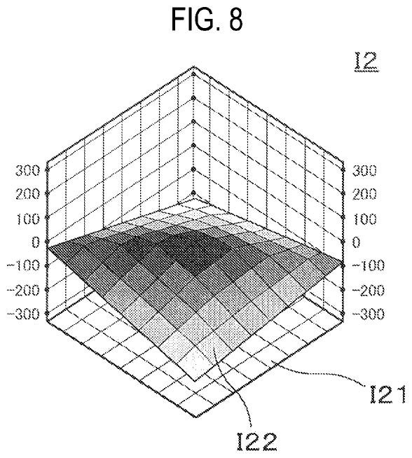

FIG. 8 is a view illustrating another exemplary probe height map image.

In a probe height map image I2 of FIG. 8, a plane 121 represents a horizontal plane and a colored curved surface 122 represents a probe height distribution. The probe height map image 12 displays a probe height distribution as a stereoscopic display image, and reflects height information in respective portions of the probe height distribution as position information regarding a direction corresponding to the vertical direction (the Z direction) in a three-dimensional space. The image I2 of FIG. 8 also represents the height information in the probe height distribution in color. However, when a stereoscopic display is performed as shown in FIG. 8, representing the height information in color may be omitted.

In addition, the probe height map images I1 and I2 in FIGS. 7 and 8, respectively, represent height information at each of 9×9 points (81 points) in the probe card 80. In the probe height map images I1 and I2 of FIGS. 7 and 8, respectively, the height information indicated in color is information on an average height of the probes 82 in each of 8×8 square regions, which are obtained by dividing a distribution display target region defined by the nine points×nine points described above in a grid pattern.

The number of height information acquisition points in a probe height map image is 9×9 points, i.e., 81 points, in the examples of FIGS. 7 and 8, but may be larger or smaller than those example.

Although not illustrated, a device height map image showing an in-plane distribution of heights of devices in a wafer W (hereinafter, referred to as a “device height distribution”) may be configured in the same manner as the probe height map image.

The image creator 93a can create a probe height map image and a device height map image as a user interface image (hereinafter, referred to as a “UI image”) including these height map images.

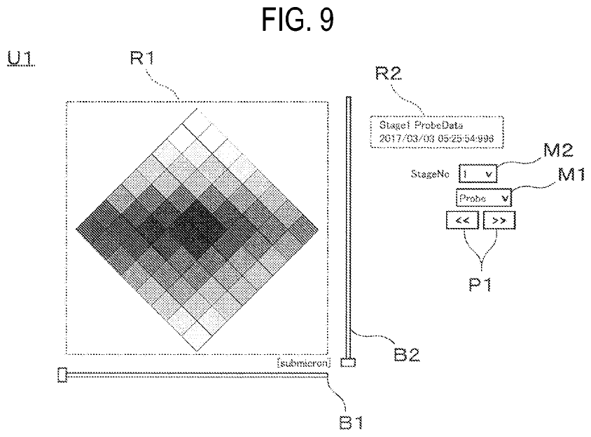

FIG. 9 is a view illustrating an exemplary UI image including a height map image. A UI image U1 of FIG. 9 includes an image display region R1, a switching pull-down menu M1, scroll bars B1 and B2, a selection pull-down menu M2, selection buttons P1, an information display region R2, and the like.

A probe height map image and a device height map image are selectively displayed in the image display region R1.

The switching pull-down menu M1 is provided for selecting whether to display the probe height map image or the device height map image in the image display region R1.

The scroll bars B1 and B2 are provided in a vicinity of the image display region R1, and are used for, for example, the following purposes:

(A) switching a display form of an image in the image display region R1 (specifically, switching between a plane display image such as the probe height map image I1 of FIG. 7 and a stereoscopic display image such as the probe height map image I2 of FIG. 8); and

(B) changing a viewpoint in the stereoscopic display image.

The image displayed in the image display region R1 of the UI image U1 reflects information acquired at the time of alignment. The selection pull-down menu M2 is provided for selecting a stage on which the alignment has been performed from a plurality of stages (spaces provided with testers 40) existing in the inspection apparatus 2.

The alignment is performed every inspection, that is, at predetermined time intervals, and the selection buttons P1 are provided for selecting alignment as a display target in the image display region R1 by designating time.

In the information display region R2, information regarding the alignment as a display target in the image display region R1 is displayed. The displayed information includes, for example, information on time at which the alignment is performed, information on a stage in which the alignment is performed, and information on whether the image displayed in the image display region R1 is related to probes or electronic devices.

Next, a method of creating a probe height map image by the image creator 93a will be described.

In the alignment in which information as a basis of a probe height map image is acquired, it is desirable that the number of measurement points for the heights of the probes 82 per each alignment be small in order to shorten the inspection time. Therefore, for example, in a single operation of alignment, the heights of the probes 82 may actually be detected only at five points, which include a central upper end, a central lower end, a central left-hand side end, a central right-hand side end, and a center of the probe card 80.

When creating the probe height map image, the image creator 93a interpolates height information in portions of the probe card 80 in which the heights of the probes 82 are not detected (hereinafter, referred to as “undetected portions”) based on the detection result of portions of the probe card 80 in which the heights of the probes 82 are actually detected (hereinafter, referred to as “actually detected portions”). Specifically, when creating the probe height map image, the image creator 93a calculates the heights of the probes 82 in the undetected portions, which are located between the actually detected portions, from the detection result in the actually detected portions. In a manner described above, the probe height map image, in which the number of points showing the heights of the probes 82 in a unit area is larger than the number of actually detected portions, is created. Of a probe height map image, which includes probe height information corresponding to only the number of actually detected portions (e.g., five points), and the probe height map image, which includes more probe height information (per unit area) than the number of actually detected portions, the user can recognize a state of the probe card 80 in a shorter time based on the latter.

Since a method of creating a device height map image by the image creator 93a is the same as the method of creating the probe height map image, the description thereof will be omitted.

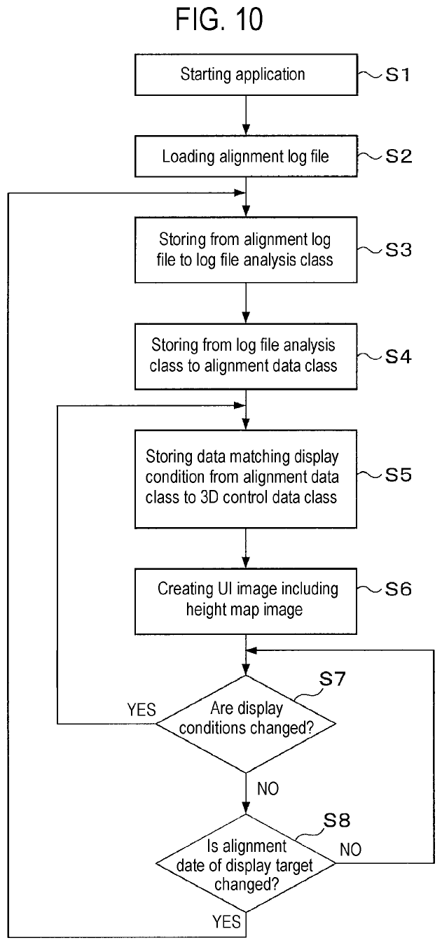

Next, an exemplary image creation process by the image creator 93a will be described. FIG. 10 is a flowchart for explaining an exemplary image creation process by the image creator 93a.

First, an application for analyzing an inspection state in the inspection apparatus 2 is started (step S1).

Subsequently, the image creator 93a loads an alignment log file, that is, expands the alignment log on a memory (not illustrated) (step S2).

The alignment log is output on a daily basis. Thus, the image creator 93a reads, for example, the alignment log for a date selected by the user when the analysis application is started, and stores predetermined information in a log file analysis class (step S3).

Subsequently, the image creator 93a executes a predetermined method included in the log file analysis class, and stores the predetermined information from the log file analysis class in an alignment data class (step S4).

Subsequently, by executing a method according to display conditions included in the alignment data class, the image creator 93a stores information matching the display conditions from the alignment data class in a 3D control data class (step S5). The display conditions are, for example, the following (a) to (c) and the like:

(a) Information, which is selected via the switching pull-down menu M1, on whether an image to be displayed in the image display region R1 of the UI image U1 is a probe height map image or a device height map image;

(b) Information, which is selected via the selection pull-down menu M2, on a stage in which alignment displayed as an image in the image display region R1 is performed; and

(c) Information, which is selected via the selection buttons P1, on a time at which alignment displayed as an image in the image display region R1 is performed.

Subsequently, a method for performing the above-mentioned interpolation related to image creation (hereinafter referred to as an “interpolation method”) included in the 3D control data class is executed, and a program for drawing the UI image U1 (including a program for creating an image (drawing object) of the image display region R1) is executed. As a result, the image creator 93a creates a probe height map image (or device height map image) including the execution result of the interpolation method and the information included in the 3D control data class, and creates the UI image U1 including the height map image (step S6). The created UI image U1 is displayed on the display part 91.

By performing image creation by using the dedicated data class for the drawing object (control) as described above, it is possible to perform high-speed image display. In other words, it is possible to switch images at high speed.

When the display conditions are changed (step S7, “YES”), the process in the image creator 93a is returned to step S5, and the information matching the changed display conditions in the alignment data class is stored in the 3D control data class. Then, by performing the process of step S6, a UI image U1 including a new probe height map image (or device height map image) is created based on the changed information.

When a date of an analysis object, that is, the display target, is changed by operation of the selection buttons P1 or the like (step S8, “YES”), the process in the image creator 93a is returned to step S3, and predetermined information in the alignment log for the changed date is stored in the log file analysis class. Then, by performing the process in step S5 and subsequent processes, a UI image U1 including a new probe height map image (or device height map image) is created.

In the above description, the image creator 93a creates both the probe height map image and the device height map image, but may create only one of the images.

In the present embodiment, the image creator 93a creates at least one of a probe height map image showing a probe height distribution in the probe card 80 as an image and a device height map showing a device height distribution in the wafer W as an image. From these height map images, the user can easily and visually recognize the probe height distribution and the device height distribution in a short time. Further, when an error occurs in the inspection result, based on the probe height distribution and the device height distribution, it is possible to determine whether the cause of the error is due to the probes or the devices. For example, in a case in which it is determined in the inspection that only some electronic devices are defective (error), when the in-plane device heights are uniform in the device height distribution and the heights of probes are large only at locations of the devices determined to have the above error in the probe height distribution, the cause of the error may be determined to be the probes.

Further, in the present embodiment, the image creator 93a creates the probe height map image and the device height map image by interpolating height information in portions of the probe card 80 and the wafer W in which heights of the probes and the devices are not actually detected based on the detection result in portions of the probe card 80 and the wafer W in which heights of the probes and the devices are actually detected. Therefore, since a density of height information is high in the distribution represented by these height map images, the user can recognize states of the probe card 80 and the wafer W in a short time. In addition, it is possible to prevent lengthening of a time required for performing alignment for creating the probe height map image and the device height map image.

According to the present embodiment, the user can recognize a temporal change (trend) in the probe height distribution and the device height distribution by, for example, selecting the selection buttons P1. Then, the user can predict a failure in the probe card 80 or the like based on the temporal change in the probe height distribution and the device height distribution.

In the examples described above, the probe height map image and the device height map image are selectively displayed, but these map images may be displayed at the same time (for example, side by side). When the map images are displayed stereoscopically at the same time, an image may be created and displayed such that both the probe height distribution and the device height distribution are shown in the same 3D space. By displaying the probe height map image and the device height map image at the same time, for example, when it is determined in the inspection that an error occurs in only some electronic devices, it is possible to more easily analyze whether the error is due to the probes or the electronic devices. It is also possible to visually image parallelism between the probes and the wafer.

In the above description, the height map image showing a distribution of the heights of the probes or the electronic devices in the horizontal plane is created and displayed as an image for analysis. In addition to such a height map image, an image showing a temporal change (trend) in the heights of the probes or the electronic devices in a specific portion in the horizontal plane may be created and displayed. At this time, a UI image including an image showing the temporal change in heights (hereinafter, referred to as a “trend image in the height direction”) may be created and displayed.

By displaying the trend image in the height direction, the user can easily recognize the temporal change in the heights of probes 82 or the electronic devices in the specific portion in the horizontal plane.

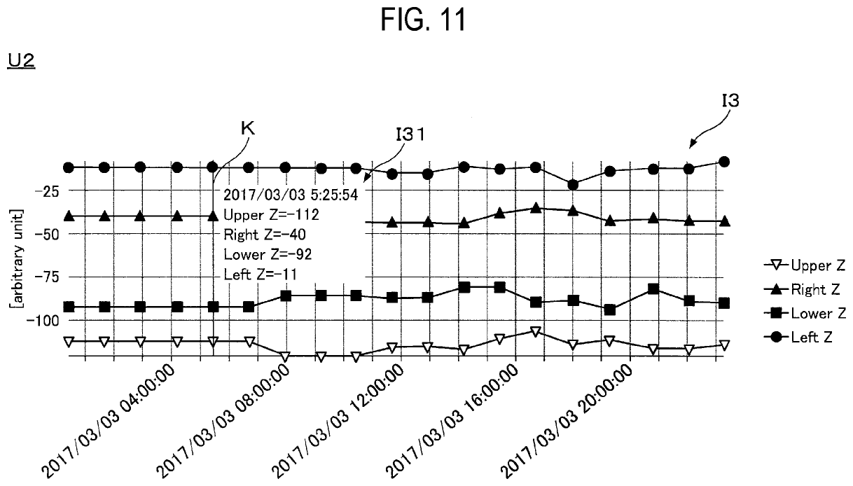

FIG. 11 is a view showing an exemplary UI image including a trend image in a height direction.

A trend image I3 in the height direction included in a UI image U2 of FIG. 11 shows a temporal change in the heights of the probes 82 within one day at each of the central upper end, the central lower end, the central left-hand side end, and the central right-hand side end of the probe card 80.

In the UI image U2, when an operation is performed on the black circles and the like, which indicate the heights of the probes 82 at a certain time, in the trend image I3, a marker K indicating an execution time of the alignment in which the information on the heights has been obtained is superimposedly displayed on the trend image I3.

In the UI image U2, a detailed information image I31 representing information on the alignment of which execution time is indicated by the marker K is superimposedly displayed in a region adjacent to the marker K on the trend image I3. The detailed information image I31 numerically indicates a date and time at which the alignment was performed and the heights of the probes 82 obtained during the alignment.

The trend image in the height direction of the electronic devices of the wafer W may have the same content as the trend image in the height direction of the probes 82.

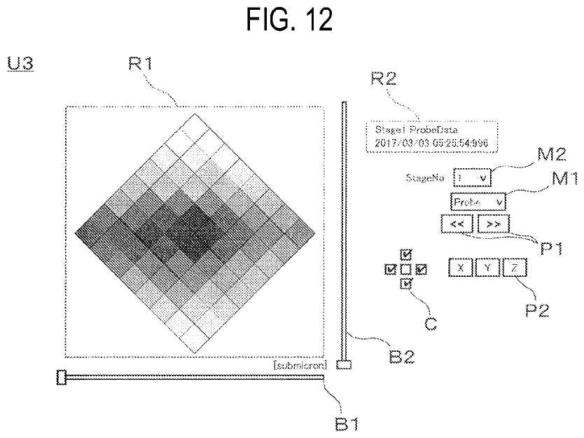

FIG. 12 is a view illustrating an exemplary UI image for displaying the UI image including the trend image in the height direction illustrated in FIG. 11.

The UI image U3 of FIG. 12 is a UI image obtained by providing check boxes C and an operation button P2 in the UI image U1 of FIG. 9.

The check boxes C are provided for designating regions to be displayed in the trend image in the height direction, in other words, for designating regions as display targets of the trend in the height direction. The check boxes C illustrate in FIG. 12 are in a state in which the central upper end, the central lower end, the central left-hand side end, and the central right-hand side end are designated as regions to be displayed in the trend image.

The operation button P2 is provided for switching from the UI image U3 to the UI image U2 including the trend image I3 in the height direction illustrated in FIG. 11. For example, when the operation button P2 is operated in a state in which the check boxes C at the four corners are selected (checked), the display is switched from the UI image U3 to the UI image U2 of FIG. 11 including the trend image in the height direction (the Z direction).

In addition, when an operation of closing the UI image U2 (an operation screen included in the UI image U2) is performed, the display is switched from the UI image U2 to the UI image U3.

In the examples described above, the UI image U3 including the height map image and the UI image including the trend image in the height direction are switchedly displayed, that is, the height map image and the trend image in the height direction are switched and displayed, but these UI images may be displayed at the same time.

In addition, in the above description, the inspection apparatus 2 and the analysis apparatus 3 are separate bodies, but the function of the analysis apparatus 3 described above may be provided in the inspection apparatus 2.

It should be understood that the embodiments disclosed herein are illustrative and are not limiting in all aspects. The above embodiments may be omitted, replaced, or modified in various forms without departing from the scope and spirit of the appended claims.

The following configurations also fall within the technical scope of the present disclosure.

(1) An analysis apparatus for analyzing a state of inspection of an object to be inspected, wherein the object to be inspected has inspection target devices formed on the object to be inspected, and the inspection is performed by using a probe card having probes, which is formed on the probe card and configured to be brought into contact with the inspection target devices, the analysis apparatus including:

a display part configured to display an image; and

an image creator configured to create the image to be displayed on the display part, and

wherein the image creator creates as the image, based on a result of detecting at least one of heights of the probes in portions of the probe card and heights of the inspection target devices in portions of the object to be inspected, a height map image showing a distribution of the heights of at least one of the probes and the inspection target devices.

According to item (1) above, the height map image showing the height distribution of at least one of the probes and the inspection target devices is created and displayed. Therefore, the user can easily and visually recognize the probe height distribution and the device height distribution from the height map image.

(2) The analysis apparatus of item (1) above, wherein the height map image shows height information in the distribution in color.

(3) The analysis apparatus of item (2) above, wherein the height map image shows the height information in the distribution by a change in at least one of brightness, saturation, and hue.

(4) The analysis apparatus of any one of items (1) to (3) above, wherein the height map image shows the distribution in a stereoscopic display.

(5) The analysis apparatus of any one of items (1) to (4) above, wherein the image creator is configured to create the height map image showing the distribution of the heights of the probes by interpolating height information in portions of the probe card in which the heights of the probes are not actually detected, based on the detection result of portions of the probe card in which the heights of the probes are actually detected, and create the height map image showing the distribution of the heights of the inspection target devices by interpolating height information in portions of the object to be inspected in which the heights of the inspection target devices are not actually detected, based on the detection result of portions of the object to be inspected in which the heights of the inspection target devices are actually detected.

(6) The analysis apparatus of any one of items (1) to (5) above, wherein the heights of the inspection target devices are heights of specific portions of the inspection target devices.

(7) An image creation method of creating an image used for analyzing a state of inspection of an object to be inspected, wherein the object to be inspected has inspection target devices formed on the object to be inspected, and the inspection is performed by using a probe card having probes, which is formed on the probe care and configured to be brought into contact with the inspection target devices, the image creation method including:

creating as the image, based on a result of detecting at least one of heights of the probes in portions of the probe card and heights of the inspection target devices in portions of the object to be inspected, a height map image showing a distribution of the heights of at least one of the probes and the inspection target devices.

### EXPLANATION OF REFERENCE NUMERALS

3: analysis apparatus, 91: display part, 93a: image creator, I1: probe height map image, I2: probe height map image, U: user interface image, W: wafer

1. An analysis apparatus for analyzing a state of inspection of an object to be inspected, wherein the object to be inspected has inspection target devices formed on the object to be inspected, and the inspection is performed by using a probe card having probes, which is formed on the probe card and configured to be brought into contact with the inspection target devices, the analysis apparatus comprising:
a display part configured to display an image; and
an image creator configured to create the image to be displayed on the display part,
wherein the image creator creates as the image, based on a result of detecting at least one of heights of the probes in portions of the probe card and heights of the inspection target devices in portions of the object to be inspected, a height map image showing a distribution of the heights of at least one of the probes and the inspection target devices.

2. The analysis apparatus of claim 1, wherein the height map image shows height information in the distribution in color.

3. The analysis apparatus of claim 2, wherein the height map image shows the height information in the distribution by a change in at least one of brightness, saturation, and hue.

4. The analysis apparatus of claim 1, wherein the height map image shows the distribution in a stereoscopic display.

5. The analysis apparatus of claim 1, wherein the image creator is configured to create the height map image showing the distribution of the heights of the probes by interpolating height information in portions of the probe card in which the heights of the probes are not actually detected, based on the detection result of portions of the probe card in which the heights of the probes are actually detected, and create the height map image showing the distribution of the heights of the inspection target devices by interpolating height information in portions of the object to be inspected in which the heights of the inspection target devices are not actually detected, based on the detection result of portions of the object to be inspected in which the heights of the inspection target devices are actually detected.

6. The analysis apparatus of claim 1, wherein the heights of the inspection target devices are heights of specific portions of the inspection target devices.

7. An image creation method of creating an image used for analyzing a state of inspection of an object to be inspected, wherein the object to be inspected has inspection target devices formed on the object to be inspected, and the inspection is performed by using a probe card having probes, which is formed on the probe card and configured to be brought into contact with the inspection target devices, the image creation method comprising:
creating as the image, based on a result of detecting at least one of heights of the probes in portions of the probe card and heights of the inspection target devices in portions of the inspection object, a height map image showing a distribution of the heights of at least one of the probes and the inspection target devices.
